(19) United States
(12) Patent Application Publication
(10) Pub. No.: US 2002/0181572 A1
(43) Pub. Date: Dec. 5, 2002

(54) Joint timing recovery and equalization for an N antenna system

(75) Inventors: Joseph P. Meehan, New York, NY (US); Xuemei Ouyang, Ossining, NY (US)

Correspondence Address: Corporate Patent Counsel, Philips Electronics North America Corporation, 580 White Plains Road, Tarrytown, NY, 10591, US

(73) Assignee: KONINKLIJKE PHILIPS ELECTRONICS N.V.

(21) Appl. No.: 09/873,567

(22) Filed: Jun. 4, 2001

(51) Int. Cl. H03K 5/159

(52) U.S. Cl. 375/229

(57) ABSTRACT

A timing recovery loop in the front end of a digital receiver includes a sample rate converter which receives a symbol stream at a first sampling rate and outputs the symbol stream at a second sampling rate responsive to a timing recovery (TR) control signal, a forward equalizer generating an equalized feedback signal based on the symbol stream at the second sampling rate, and a timing recovery circuit generating the TR control signal based upon the equalized feedback signal. If desired, the timing recovery loop may include a carrier recovery circuit electrically coupling the sample rate converter to the forward equalizer and a finite impulse response (FIR) filter electrically coupling the carrier recovery circuit to the forward equalizer. In an exemplary case, the FIR filter is a square-root raised cosine filter. A method for controlling the timing recovery loop based on the equalized feedback signal and a corresponding timing recovery control signal are also described.

### BACKGROUND OF THE INVENTION

1. Field of the Invention

The present invention relates generally to a timing recovery circuitry for an antenna system. More specifically, the present invention relates to joint timing recovery and equalization circuitry for an N antenna system. Corresponding methods are also disclosed.

2. Discussion of Related Art

A digital transmission is susceptible to multipath fading or the like and invites waveform distortion of the transmitted signal resulting in degradation of signal quality. In order to minimize this problem, it is the current practice to employ an automatic adaptive equalizer using a transversal filter. An adaptive equalizer may be classified into linear and non-linear types. Linear equalization has found extensive use in terrestrial digital communications systems. However, it is unable to effectively minimize deep or severe multipath distortion. Therefore, residual intersymbol interference undesirably increases. In particular, as a signal transmission rate becomes higher and signal propagation distance increases, the linear equalization is no longer sufficient to handle severe frequency selective fading wherein multipath delay spreads over a transmission symbol period. To overcome this problem, a non-linear type equalizer, which takes the form of a decision feedback equalizer (DFE), is often employed.

It will be appreciated that the DFE includes both a forward equalizer (FE) and a feedback equalizer (FBE). Furthermore, the DFE includes a decision circuit or decision device DD and a subtractor. In operation, the DFE is supplied with, for example, an incoming QAM signal and operates to minimize intersymbol interference (ISI) due to a precursor of an impulse response at the forward equalizer FE, while minimizing ISI caused by a postcursor at the feedback equalizer FBE. The output of the forward equalizer FE is subtracted from the output of the feedback equalizer at the subtractor. The decision signal output from the decision device DD and then fed back to the feedback equalizer FBE, is free of intersymbol interference and noises. Therefore, the equalization capability of the feedback equalizer FBE using the decision feedback technique, is higher than that of the forward equalizer FE. This means that the backward equalizer is capable of completely removing ISI caused by a postcursor of impulse response (viz., minimum phase shift fading). It goes without saying that the DFE is superior to the case where only the forward equalizer FE is provided, which has the same function as the linear equalizer mentioned above.

On the other hand, intersymbol interference due to a precursor (non-minimum phase shift fading) is equalized at the forward equalizer FE whose function equals that of the linear equalizer. Consequently, in connection with the ISI due to non-minimum phase shift fading, the DFE merely implements equalization which is identical to that of the forward equalizer FE. This is the reason why an easily installed linear equalizer FE is chiefly employed, rather than a complex DFE, in terrestrial digital microwave communications systems even though severe distortions due to non-minimum phase fading occurs frequently.

The ATSC standard set forth by the Advanced Television Systems Committee in the document entitled “ATSC Digital Television Standard” (Document A53, Sep. 16, 1995), for terrestrial Digital TV in the United States requires transmission of an MPEG bit stream of 19.28 Mbps over a bandwidth of 6 MHz at a symbol rate of 10.76 MHz in the VHF and UHF carrier frequency range. The modulation scheme used is a single carrier 8 level Vestigial Sideband (VSB) modulation scheme.

Many digital television receivers have internal antennas or are connected to indoor antennas. In such digital television receivers, there can be problems in receiving a good quality signal due to the presence of multiple signal echoes created by obstacles in the room. The multiple signal echoes are inteferer signals that arrive late or early at the antenna (i.e., multipath delay). In cases where the television receiver is connected to a readily accessible indoor antenna, the indoor antenna may be manually rotated or adjusted to maximize the main signal and minimize the unwanted signals created by the multiple signal echoes of the main signal. In cases where the television receiver has an internal antenna that is not readily accessible, one must manually rotate or adjust the entire television receiver in order to make the desired adjustment.

The analysis of current synchronization algorithms for reception of ATSC Terrestrial DTV signals indicates that they are liable to fail in situations where there is significant Intersymbol Interference (ISI). Since the next generation in US Terrestrial DTV receivers will incorporate multiple antennae, and since current synchronization algorithms will not work for multiple antenna inputs, this problem will only get worse. In other words, new synchronization algorithms are and will be required.

As discussed above, in order to compensate for ISI and other sources of signal degradation and distortion, an equalizer, e.g., a fractionally spaced adaptive filter, is included in the receiver. It will be appreciated that an adaptive filter can modify, from time instant to time instant, the coefficients, also referred to as tap weights, used in the filter to remove ISI and to compensate for amplitude and group delay distortions. The update of the tap weights is done to minimize the error between the output of the filter and its expected or sliced value, i.e. the nearest constellation point. This error is effectively a measure of the difference between the actual output of the filter and the expected output. The adaptive process continues until the error is at a minimum, i.e., the filter converges.

The quality of convergence of an equalizer depends on many factors including the number of taps, initial tap weights, desired convergence rate, signal to noise ratio (SNR) at the input and phase changes caused by a timing recovery circuit at the receiver, and can be accomplished with various adaptive algorithms.

One point of failure in the receiver is illustrated in FIG. 1, which depicts Timing Recovery (TR) circuitry employed in conventional chipsets. In FIG. 1, a digital television (DTV) receiver 1 includes a sample rate converter (SRC) 10, a carrier recovery (CR) circuit 12, a square-root raised cosine (SQRC) filter 14 (e.g., a finite impulse response (FIR) filters with a square root of a raised cosine characteristic such as described in U.S. Pat. No. 6,216,250 to Williams), a forward equalizer (FE) 16, a sync detector (SD) 18, an arithmetic device 30, and a decision device (DD) 40 arranged in that order. Timing recovery (TR) circuitry 20 receives the output of the SQRC filter 14 and generates a TR control signal which is applied to a control input terminal of SRC 10. It will also be noted that the output of DD 40 is applied to a Feedback Equalizer 50, the output of which is applied to a second input port of the arithmetic device 30.

Preferably, the sample rate converter can be similar to that disclosed in U.S. Pat. No. 6,141,671 to Adams, et al, which discloses circuitry for converting a sequence of input samples at a first sampling rate defining an input period to a sequence of output samples at a second sampling rate. Moreover, the carrier recovery circuit can take numerous forms, such as that disclosed in U.S. Pat. No. 6,192,088 Aman et al., which describes a digital carrier recovery system that includes acquisition and tracking modes of operation. It will be appreciated that this carrier recovery circuit seeks and locks to the long term frequency offset of the received carrier signal circuit in the acquisition mode while tracking the instantaneous variations in the carrier phase in the tracking mode. Furthermore, it will be appreciated that decision-directed timing recovery circuitry for a VSB signal receiver adjusts the frequency and phase of the sampling clock to optimize the timing of samples, i.e., to insure that the sampling is in temporal alignment with the transmission of symbols on the VSB carrier. The timing recovery circuitry advantageously can be of the same general type as S. U. H. Qureshi described for use with pulse amplitude modulation (PAM) signals in his paper “Timing Recovery for Equalized Partial-Response Systems”, IEEE Transactions on Communications, December 1976, pp. 1326-1333. All of the patents and references mentioned above are incorporated by reference.

It will be understood from FIG. 1 that the TR circuitry and corresponding algorithm (software) is in the front end of the DTV receiver 1 and, hence, always sees the complete distorted channel. In some cases, a heavily distorted channel can mean that the TR algorithm cannot achieve a synchronization lock and, thus, the performance of the complete receiver system is markedly reduced.

What is need is a method for generating a timing recovery signal and circuitry for generating same which is resistant to synchronization loss. What is also needed is a method and corresponding circuitry that is independent of the number of antenna inputs. It would be beneficial if the thus improved method and corresponding circuitry could be implement at little or no additional cost.

### SUMMARY OF THE INVENTION

Based on the above and foregoing, it can be appreciated that there presently exists a need in the art for joint timing recovery and equalization methods for an N antenna system which overcomes the above-described deficiencies. The present invention was motivated by a desire to overcome the drawbacks and shortcomings of the presently available technology, and thereby fulfill this need in the art.

According to one aspect, the present invention provides a timing recovery control signal generated in a timing recovery loop based upon an equalized feedback signal.

According to another aspect, the present invention provides a timing recovery loop in the front end of a digital receiver, including a sample rate converter which receives a symbol stream at a first sampling rate and outputs the symbol stream at a second sampling rate responsive to a timing recovery (TR) control signal, a forward equalizer generating an equalized feedback signal based on the symbol stream at the second sampling rate, and a timing recovery circuit generating the TR control signal based upon the equalized feedback signal. If desired, the timing recovery loop may include a carrier recovery circuit electrically coupling the sample rate converter to the finite impulse response (FIR) filter and a finite impulse response (FIR) filter electrically coupling the carrier recovery circuit to the forward equalizer. In an exemplary case, the FIR filter is a square-root raised cosine filter.

According to a further aspect, the present invention provides a digital receiver connected to N antennae including N timing recovery loops electrically coupled to the N antennae, each of the N timing recovery loops constructed as described immediately above.

According to a still further aspect, the present invention provides a timing recovery loop in the front end of a digital receiver including N antennae, including N sample rate converters which receive an Nth symbol stream at a first sampling rate from an Nth antenna and outputs the Nth symbol stream at a second sampling rate responsive to a timing recovery (TR) control signal, N forward equalizers generating an Nth equalized feedback signal based on the Nth symbol stream at the second sampling rate, respectively, and a timing recovery circuit generating the TR control signal based upon the N equalized feedback signals.

According to a further aspect, the present invention provides a timing recovery loop in the front end of a digital receiver including N antennae, including N sample rate converters, each receiving an Nth symbol stream at a first sampling rate from an Nth antenna and outputting the Nth symbol stream at a second sampling rate responsive to a timing recovery (TR) control signal, N forward equalizers, each generating an Nth equalized feedback signal based on the Nth symbol stream at the second sampling rate, respectively, and a timing recovery circuit generating the TR control signal based upon a selected one of the N equalized feedback signals. Preferably, the timing recovery loop includes a selector receiving N signals based on the N equalized feedback signals at N respective input terminals and applying the selected one of the N signals to the timing recovery circuit.

According to another aspect, the present invention provides a method for operating a digital receiver including a sample rate converter responsive to a timing recovery (TR) control signal, including steps for generating an equalized feedback signal based on a symbol stream having a controlled sample rate, producing the TR control signal based on the equalized feedback signal, and applying the TR control signal to the sample rate converter to thereby permit the sample rate converter to output the symbol stream at the controlled sample rate.

According to yet another aspect, the present invention provides a method for operating a digital receiver, including N sample rate converters responsive to a timing recovery (TR) control signal, connected to N antennae, respectively, including steps for generating N equalized feedback signals, each based on an Nth symbol stream having a controlled sample rate, combining the N equalized feedback signal to produce a combined equalized feedback signal, producing the TR control signal based on the combined equalized feedback signal, and applying the TR control signal to the sample rate converter to thereby permit the N sample rate converters to output N symbol streams at the controlled sample rate.

According to a still further aspect, the present invention provides a method for operating a digital receiver, including N sample rate converters responsive to a timing recovery (TR) control signal, connected to N antennae, respectively. Preferably, the method includes steps for generating N equalized feedback signals, each based on an Nth symbol stream having a controlled sample rate, selecting one of the N equalized feedback signals to produce a selected equalized feedback signal, producing the TR control signal based on the selected equalized feedback signal, and applying the TR control signal to the sample rate converter to thereby permit the N sample rate converters to output N symbol streams at the controlled sample rate.

### BRIEF DESCRIPTION OF THE DRAWINGS

These and various other features and aspects of the present invention will be readily understood with reference to the following detailed description taken in conjunction with the accompanying drawings, in which like or similar numbers are used throughout, and in which:

FIG. 1 is a high-level block diagram of a conventional timing recovery loop implemented in a DTV receiver;

FIG. 2 is a high-level block diagram of one preferred embodiment of a timing recovery loop implemented in a DTV receiver according to the present invention;

FIG. 3 is a high-level block diagram of a second preferred embodiment of a timing recovery loop implemented in a DTV receiver according to the present invention, which receiver is connected to an antenna array; and

FIG. 4 is a high-level block diagram of a third preferred embodiment of an adaptive timing recovery loop implemented in a DTV receiver according to the present invention.

### DETAILED DESCRIPTION OF THE PREFERRED EMBODIMENTS

The present invention provides a digital television receiver, which combines equalization and the Timing Recovery functions. More specifically, the DTV receiver according to the present invention utilizes an equalized signal as the input to the Timing Recovery loop.

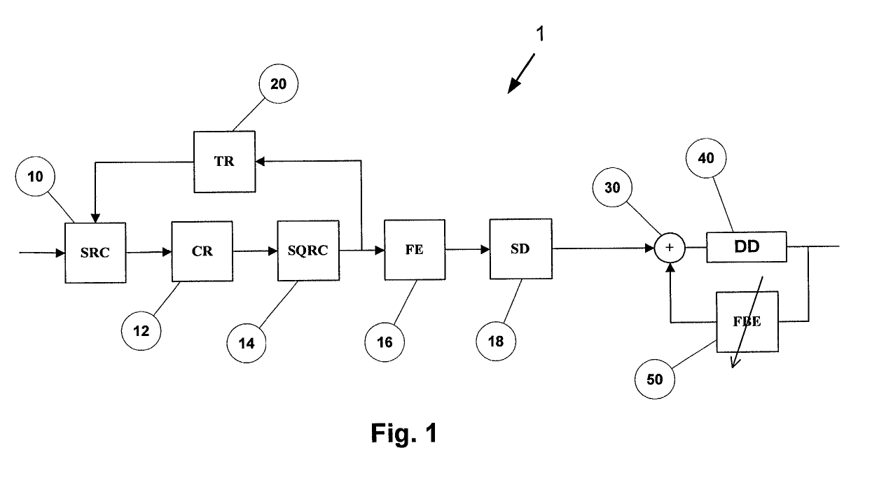

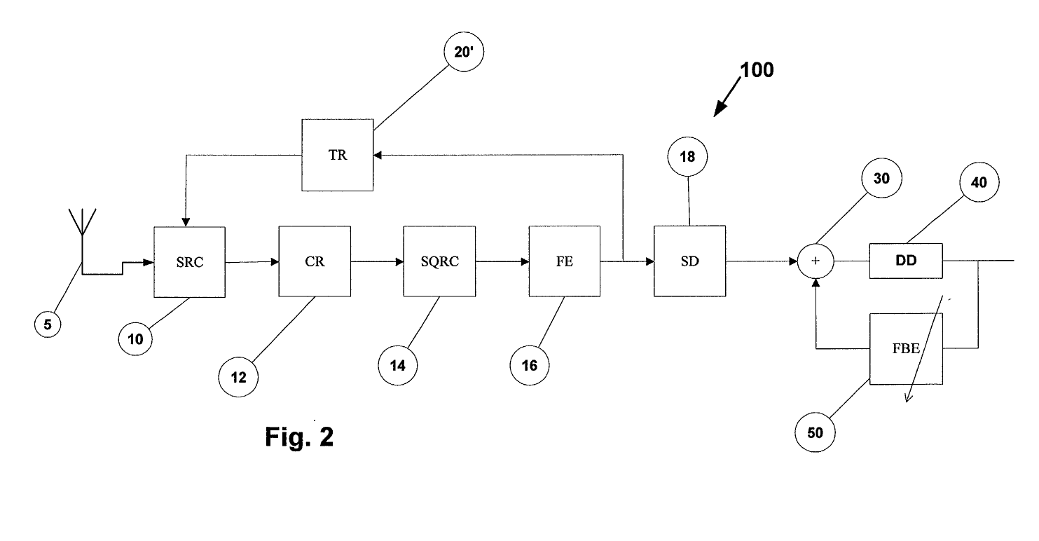

A preferred embodiment of a DTV receiver 100 according to the present invention is illustrated as being connected to an antenna 5 in FIG. 2. The DTV receiver includes a sample rate converter (SRC) 10, a carrier recovery (CR) circuit 12, a square-root raised cosine (SQRC) filter 14, a forward equalizer (FE) 16, a sync detector (SD) 18, an arithmetic device 30, and a decision device (DD) 40 arranged similar to the arrangement illustrated in FIG. 1. However, in FIG. 2, the timing recovery (TR) circuitry 20′ receives the output of the FE 16 and generates a TR control signal, which is applied to a control input terminal of SRC 10. It will also be noted that the output of DD 40 is applied to a Feedback Equalizer 50, the output of which is applied to a second input port of the arithmetic device 30, as previously discussed.

In other words, in the DTV receiver implementation illustrated in FIG. 1, the feedback signal applied to the timing recovery (TR) loop is at the output of the SQRC filter 14. In contrast, in the preferred embodiment of the present invention depicted in FIG. 2, the feedback signal applied to the TR loop is generated downstream of the SQRC filter and constitutes an equalized feedback signal. It will be appreciated that the equalized feedback signal advantageously can be the output of the forward equalizer (FE) or the output of the complete Decision Feedback Equalizer (DFE). It will also be appreciated that utilization of the equalized feedback signal as the input into the TR loop will necessarily be a cleaner signal and, hence, maximize the possibility of achieving a synchronization lock under degraded channel conditions.

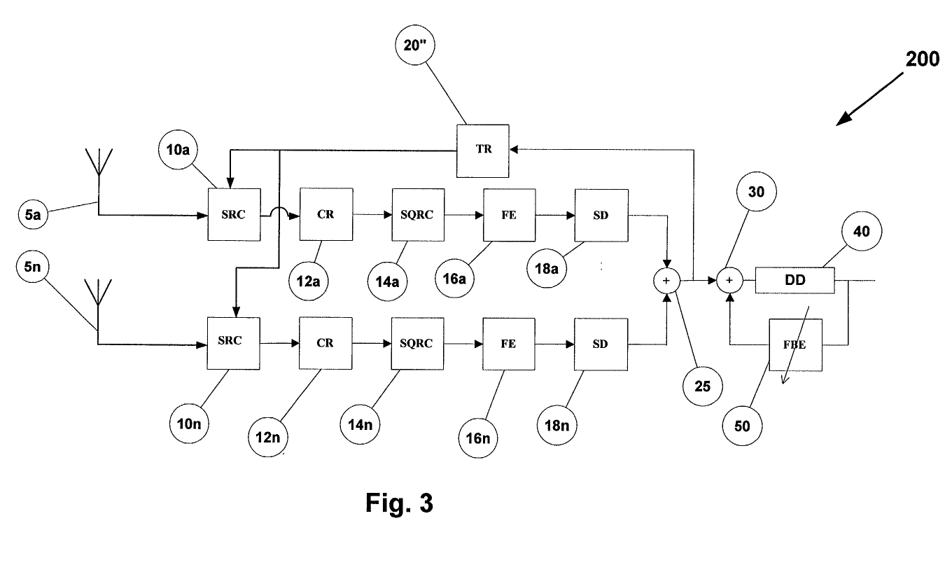

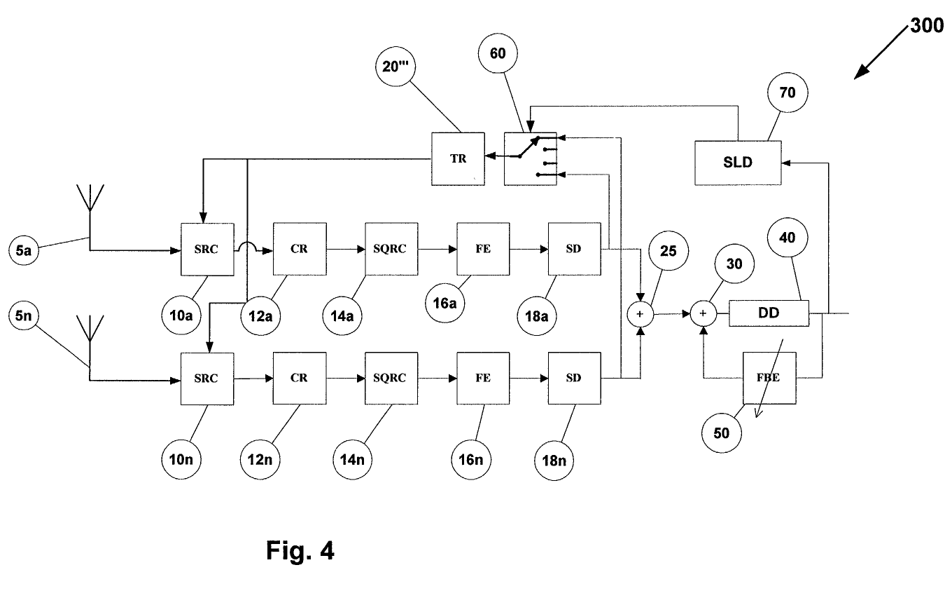

The proposed next generation of US Terrestrial DTV receivers will incorporate multiple antenna inputs. It will be appreciated that the preferred embodiment of the preferred invention illustrated in FIG. 2 would not provide an optimal solution to the timing recovery problem since there would now be multiple inputs in need of synchronization. There are several was to adapt the inventive technique to a multiple antenna environment. First, the DTV receiver could advantageously include only one TR loop; the input to the TR loop would be the equalized feedback signal derived from combined output of all the antennae. This is shown in FIG. 3. Alternatively, the TR algorithm could be implemented with an independent TR loops for each antenna. It could also be implemented by a single TR circuit generating a common TR control signal applied to all of the SCR circuits in the DTV receiver; in that case, the DTV receiver would require a switch permitting the equalized feedback signal providing the optimal synchronization lock to be applied to the TR circuit. This arrangement, which represents yet another preferred embodiment of the present invention, is depicted in FIG. 4 and will be discussed below.

As mentioned above, another preferred embodiment of the DTV receiver according to the present invention, which permits the adaptation of an equalization structure to a beamforming antenna system to thereby produce an adaptive Digital Broadband Beamforming (DBBF) receiver system for receiving an ATSC 8-VSB signal, is illustrated in FIG. 3. More specifically, FIG. 3 illustrates a high-level block diagram of an adaptive DBBF receiver system 200 connected to antennae 5a, . . . , 5n, which includes a sample rate converter (SRC) 10a, a carrier recovery (CR) circuit 12a, a square-root raised cosine (SQRC) filter 14a, a forward equalizer (FE) 16a, a sync detector (SD) 18a, and an arithmetic device 25. Moreover, the receiver system 200 includes a sample rate converter (SRC) 10n, a carrier recovery (CR) circuit 12n, a square-root raised cosine (SQRC) filter 14n, a forward equalizer (FE) 16n, a sync detector (SD) 18n. The output of SD 18n is applied to another input port of the arithmetic device 25. It will be appreciated that any number N of antennas can be accommodated using the front-end arrangement illustrated in FIG. 3. The output of arithmetic device 25 is applied to a decision device (DD) 40 via a second arithmetic device 30. It will also be noted that the output of DD 40 is applied to a Feedback Equalizer 50, the output of which is applied to a second input port of the arithmetic device 30.

In the DTV receiver 200 illustrated in FIG. 3, the timing recovery (TR) circuitry 20″ receives the output of the arithmetic device 25 and generates a TR control signal, which is applied to a control input terminal of SRC 10. It will be appreciated that the output of arithmetic device 25, while being an equalized feedback signal, represent the combination of all of the signals from the various antennas 5a, . . . , 5n received by the DTV receiver 200. It will be appreciated that this may not be the optimum technique for generating and/or selecting the equalized feedback signal needed by the TR loop.

FIG. 4 illustrates a high-level block diagram of an adaptive DBBF receiver system 300 connected to antennae 5a, . . . , 5n, which includes a sample rate converter (SRC) 10a, a carrier recovery (CR) circuit 12a, a square-root raised cosine (SQRC) filter 14a, a forward equalizer (FE) 16a, a sync detector (SD) 18a, and an arithmetic device 25. Moreover, the DTV receiver 300 includes a sample rate converter (SRC) 10n, a carrier recovery (CR) circuit 12n, a square-root raised cosine (SQRC) filter 14n, a forward equalizer (FE) 16n, a sync detector (SD) 18n. The output of SD 18n is applied to another input port of the arithmetic device 25. It will be appreciated that any number N of antennas can be accommodated using the front-end arrangement illustrated in FIG. 3. The output of arithmetic device 25 is applied to a decision device (DD) 40 via a second arithmetic device 30. It will also be noted that the output of DD 40 is applied to a Feedback Equalizer 50, the output of which is applied to a second input port of the arithmetic device 30.

As with the receiver system 200 illustrated in FIG. 3, the receiver system 300 include TR circuitry 20′″ generating a TR control signal which can be applied to all of the SCR circuits 10a, . . . , 10n. Preferably, the input of the TR circuit 30′″ is provided by a selector switch 60, e.g., a multiplexer, which advantageously can connect one of the several equalized feedback signals generated by the receiver system 300 to the TR circuitry. In an exemplary case, the selector switch 60 receives equalized feedback signals EFSa, . . . , EFSn output by sync detectors 18a, . . . , 18n, respectively. Advantageously, selector switch 60 can be operated by a sync lock detector 70, which can receive an output signal from a convenient downstream component, e.g., the output of decision device 40.

From the discussion above, it will be appreciated that there are two main advantages to this novel method of Timing Recovery. Primarily, the overall performance of the Timing Recovery loop will be noticeably improved due primarily to the fact that the equalized feedback signal going into the TR loop is relatively clean (in contrast to the output of the SQRC filter. Thus, the DTV receiver according to the present invention will achieve synchronization lock even in severely degraded channel conditions. Secondly, the Timing Recovery system and corresponding method advantageously is more amenable to increasing the number of antenna inputs, since the DTV receiver can be implemented with only one Timing Recovery loop. It will also be appreciated that the advantages, and others that are readily apparent to one of ordinary skill in the art, can be implemented while incurring little or no additional costs.

It should be mentioned that while the discussion of the preferred embodiments addressed applications involving DTV receivers, the invention is not limited to such applications. Thus, although presently preferred embodiments of the present invention have been described in detail herein, it should be clearly understood that many variations and/or modifications of the basic inventive concepts herein taught, which may appear to those skilled in the pertinent art, will still fall within the spirit and scope of the present invention, as defined in the appended claims.

What is claimed is:

1. A timing recovery control signal generated in a timing recovery loop based upon an equalized feedback signal.

2. A timing recovery loop in the front end of a digital receiver, comprising:
a sample rate converter which receives a symbol stream at a first sampling rate and outputs the symbol stream at a second sampling rate responsive to a timing recovery (TR) control signal;
a forward equalizer generating an equalized feedback signal based on the symbol stream at the second sampling rate; and
a timing recovery circuit generating the TR control signal based upon the equalized feedback signal.

3. The timing recovery loop as recited in claim 2, further comprising a carrier recovery circuit electrically coupling the sample rate converter to the forward equalizer.

4. The timing recovery loop as recited in claim 3, further comprising a finite impulse response (FIR) filter electrically coupling the carrier recovery circuit to the forward equalizer.

5. The timing recovery loop as recited in claim 4, wherein the FIR filter is a square-root raised cosine filter.

6. A digital receiver connected to N antennae including N timing recovery loops electrically coupled to the N antennae, each of the N timing recovery loops constructed as recited in claim 2.

7. A timing recovery loop in the front end of a digital receiver including N antennae, comprising:
N sample rate converters which receive an Nth symbol stream at a first sampling rate from an Nth antenna and outputs the Nth symbol stream at a second sampling rate responsive to a timing recovery (TR) control signal;
N forward equalizers generating an Nth equalized feedback signal based on the Nth symbol stream at the second sampling rate, respectively; and
a timing recovery circuit generating the TR control signal based upon the N equalized feedback signals.

8. The timing recovery loop as recited in claim 7, further comprising N carrier recovery circuits, each electrically coupling an Nth one of the N sample rate converters to an Nth one of the forward equalizers.

9. The timing recovery loop as recited in claim 8, further comprising N finite impulse response (FIR) filters, each electrically coupling an Nth one of the carrier recovery circuits to an Nth one of the forward equalizers.

10. The timing recovery loop as recited in claim 9, wherein each of the N FIR filters is a square-root raised cosine filter.

11. A timing recovery loop in the front end of a digital receiver including N antennae, comprising:
N sample rate converters, each receiving an Nth symbol stream at a first sampling rate from an Nth antenna and outputting the Nth symbol stream at a second sampling rate responsive to a timing recovery (TR) control signal;
N forward equalizers, each generating an Nth equalized feedback signal based on the Nth symbol stream at the second sampling rate, respectively; and
a timing recovery circuit generating the TR control signal based upon a selected one of the N equalized feedback signals.

12. The timing recovery loop as recited in claim 11, further comprising N carrier recovery circuits, each electrically coupling an Nth one of the N sample rate converters to an Nth one of the forward equalizers.

13. The timing recovery loop as recited in claim 12, further comprising N finite impulse response (FIR) filters, each electrically coupling an Nth one of the carrier recovery circuits to an Nth one of the forward equalizers.

14. The timing recovery loop as recited in claim 13, wherein each of the N FIR filters is a square-root raised cosine filter.

15. The timing recovery loop as recited in claim 11, further comprising a selector receiving N signals based on the N equalized feedback signals at N respective input terminals and applying the selected one of the N signals to the timing recovery circuit.

16. A method for operating a digital receiver including a sample rate converter responsive to a timing recovery (TR) control signal, comprising:
generating an equalized feedback signal based on a symbol stream having a controlled sample rate;
producing the TR control signal based on the equalized feedback signal; and
applying the TR control signal to the sample rate converter to thereby permit the sample rate converter to output the symbol stream at the controlled sample rate.

17. A method for operating a digital receiver, including N sample rate converters responsive to a timing recovery (TR) control signal, connected to N antennae, respectively, comprising:
generating N equalized feedback signals, each based on an Nth symbol stream having a controlled sample rate;
combining the N equalized feedback signal to produce a combined equalized feedback signal;
producing the TR control signal based on the combined equalized feedback signal; and
applying the TR control signal to the sample rate converter to thereby permit the N sample rate converters to output N symbol streams at the controlled sample rate.

18. A method for operating a digital receiver, including N sample rate converters responsive to a timing recovery (TR) control signal, connected to N antennae, respectively, comprising:
generating N equalized feedback signals, each based on an Nth symbol stream having a controlled sample rate;
selecting one of the N equalized feedback signals to produce a selected equalized feedback signal;
producing the TR control signal based on the selected equalized feedback signal; and
applying the TR control signal to the sample rate converter to thereby permit the N sample rate converters to output N symbol streams at the controlled sample rate.
